(19) United States
(12) Patent Application Publication
(10) Pub. No.: US 2026/0043759 A1
(43) Pub. Date: Feb. 12, 2026

(54) SINGLE CRYSTAL SAPPHIRE COMPONENT FOR ANGULAR CONTROL DURING SOLID STATE NUCLEAR MAGNETIC RESONANCE MEASUREMENTS

(71) Applicant: Rutgers, The State University of New Jersey, New Brunswick, NJ (US)

(72) Inventors: Thomas Michael OSBORN POPP, Cranford, NJ (US); Andrew J. NIEUWKOOP, Metuchen, NJ (US)

(21) Appl. No.: 18/998,662

(22) PCT Filed: Jul. 25, 2023
(86) PCT No.: PCT/US23/70894

§ 371 Date: Jan. 27, 2025

Related U.S. Application Data
(60) Provisional application No. 63/391,892, filed on Jul. 25, 2022.

(51) Int. Cl. G01N 24/08; C30B 29/20; G01R 33/30; G01R 33/46

(52) U.S. Cl. CPC G01N 24/08; C30B 29/20; G01R 33/307; G01R 33/4616

(57) ABSTRACT

An article includes a cylinder of single crystal sapphire for use during solid state nuclear magnetic resonance (SSNMR) measurements. The axis of the cylinder is aligned with an axis of symmetry of the single crystal. The cylinder is configured to rotate at a known angle and known fraction of an angular velocity as the sample during operation of the SSNMR system. In some uses, a current angle of a stator is determined based on separation of peaks in a measured signal from aluminum atoms in the sapphire crystal. Stator orientation is adjusted until the current angle is within a desired tolerance of a target angle, including one different from a magic angle.

### BACKGROUND

Nuclear magnetic resonance studies magnetic nuclei by aligning them with an applied constant magnetic field (B0) in direction z and perturbing this alignment using an alternating magnetic field (B1) at radio frequencies (called RF pulses), orthogonal to z. The resulting response to the perturbing magnetic field is the phenomenon that is exploited in nuclear magnetic resonance (NMR).

The elementary particles, neutrons and protons, composing an atomic nucleus, have the intrinsic quantum mechanical property of spin. The overall spin of the nucleus is determined by the spin quantum number I. If the number of both the protons and neutrons in a given isotope are even, then I=0. In other cases, however, the overall spin is non-zero. A non-zero spin is associated with a non-zero magnetic moment, μ, as given by Equation 1a.

$$μ = r I \qquad ( 1 a )$$

where the proportionality constant, γ, is the gyromagnetic ratio. It is this magnetic moment that is exploited in NMR. Without an external magnetic field, the spins are randomly oriented. In the presence of a magnetic field, nuclei that have a spin of one-half, like Hydrogen nuclei (¹H), have two possible spin states (aligned with the applied field, referred to as spin up, and anti-aligned, referred to as spin down) with respect to the external magnetic field. The interaction between the nuclear magnetic moment and the external magnetic field means the two states do not have the same energy. The energy difference between the two states is given by Equation 1b.

$$Δ E = ℏ γ {B}_{0} \qquad ( 1 b )$$

where ℏ is Plank's reduced constant. While most atoms are still oriented randomly, in thermal equilibrium, more than average atoms will be in the lower energy state and fewer than average in the high energy state imparting a net magnetization vector in the direction of the applied external magnetic field.

Resonant absorption will occur when electromagnetic radiation of the correct frequency to match this energy difference is applied. The energy of photons of electromagnetic radiation is given by Equation 2.

$$E = h f \qquad ( 2 )$$

where f is the frequency of the electromagnetic radiation and h=2 πℏ. Thus, absorption will occur when the frequency is given by Equation 3.

$$f = γ {B}_{0} / ( 2 π ) \qquad ( 3 )$$

The NMR frequency f is shifted by the ‘shielding’ effect of the surrounding electrons. In general, this electronic shielding reduces the magnetic field at the nucleus (which is what determines the NMR frequency). As a result, the energy gap is reduced, and the frequency required to achieve resonance is also reduced. This shift of the NMR frequency due to the chemical environment is called the chemical shift, and it explains why NMR is a direct probe of chemical structure. Gradually the high energy state nuclei lose their excess energy to the lower state nuclei and return to a random distribution at an exponential decay rate called the T1 relaxation time.

Applying a short electromagnetic pulse in the radio frequency range to a set of nuclear spins induces a transition between states of the spins. In terms of the net magnetization vector (which is due to the fact that while many nuclei are randomly arranged, there is some alignment in the spins, i.e., more nuclei have nuclear magnetic moments aligned than anti-aligned with the field), this corresponds to tilting the net magnetization vector away from its equilibrium position (aligned in the z direction along the external magnetic field, B₀). The out-of-equilibrium magnetization vector processes about the external magnetic field at the NMR frequency of the spins. This oscillating magnetization induces a current in a nearby pickup coil acting as a radio frequency (RF) receiver, creating an electrical signal oscillating at the NMR frequency.

A portion of this time domain signal (intensity vs. time), after all radio frequency pulses, is known as the free induction decay (FID) and contains the sum of the NMR responses from all the excited spins and all their chemical shielding effects. In order to obtain the frequency-domain NMR spectrum (intensity vs. frequency), this time-domain signal is Fourier transformed. After the RF pulse ends, the energy in the emitted FID signal decreases at an exponential rate called the T₂ relaxation time. The T₂ relaxation time is the time for precessing nuclei to fall out of alignment with each other (i.e., lose coherence) and thus stop producing a signal.

Solid state NMR spectroscopy (SSNMR) is a non-destructive technique that enables chemical site-specific analysis of materials and insoluble or large biological systems. To achieve high resolution NMR spectra of solids, a technique known as magic angle spinning (MAS, though in this context “spinning” refers to a reorientation rotation and not to nuclear quantum spin states) can be employed to average out anisotropic nuclear spin interactions by rapidly reorienting the sample about an axis inclined at 54.74° (the ‘magic angle’) with respect to the magnetic field.

Typically, solid samples are packed within a cylindrical rotor, which is rotated pneumatically within a radiofrequency coil housed in a stator for excitation and detection of the NMR signal. Several interactions which perturb the energies of these states, such as the chemical shift anisotropy, dipolar coupling, and quadrupolar coupling, vary based on the orientation of the interaction tensor with respect to the external magnetic field. In solution state samples, these interactions are averaged out by rapid molecular motion, but in solids, the anisotropy results in significant broadening of spectral resonances, which can hinder high-resolution analysis.

The magic angle is the angle for which the orientational term of many nuclear spin Hamiltonians to first order is equal to zero. The orientation term goes as 3 cos² θ−1, where θ is the angle relative to the magnetic field. A value of 54.74 degrees (the magic angle) causes the 3 cos² θ term to equal 1, causing the expression to go to zero.

Because the effects of magic angle miss-set are more noticeable for quadrupolar nuclei, a common method for setting the magic angle is look at the spectrum of the quadrupolar nuclide ⁷⁹Br in the salt KBr. The advantages are that KBr is a cheap and simple to handle salt, ⁷⁹Br is about 50% naturally abundant, and under magic angle spinning spectra exhibit sideband manifolds with intensities that are very sensitive to any offset from the magic angle. Another major benefit of ⁷⁹Br (as there are dozens of similarly sensitive nuclei) is that ⁷⁹Br's gyromagnetic ratio of 25.05 is very similar to the gyromagnetic ratio of ¹³C, which is 25.15. Thus, a probe which can detect ¹³C (an exceedingly common nuclei on which to do NMR given the ubiquity of carbon in biology and chemistry) can also detect ⁷⁹Br. This allows a user to quickly check/set the magic angle using a standard sample (oftentimes KBr mixed with another solid, adamantane, that allows a check for the exact strength and homogeneity of the magnetic field) without needing to change anything within the probe afterwards. One then changes back to the desired sample and proceeds with an experiment.

However, this approach has a major drawback. While removing a sample will have no effect on the magnetic field, physical manipulations of the stator to get the rotor assembly in and out, which usually requires detaching an entire probe (including the stator and rotor assembly) from the magnet and reinserting the probe, has the potential to disturb the carefully set angle of the stator. In addition, changes in the reorientation rate or sample temperature could also alter this angle as heating and additional gas flows subtly alter the position of the rotor assembly and/or stator.

### SUMMARY

The inventors recognized that being able to set and check the rotor angle using the scientifically relevant target sample instead of a separate standard would eliminate a major source of error. Techniques are provided for using a single crystal of sapphire to set stator axis angles during solid state nuclear magnetic resonance (SSNMR) measurements. While the prior art has used sapphire rotor bodies due to their optical and microwave transparent properties and thermal conductivity, those rotors are more prone to fracturing when compared to more commonly used zirconia rotors.

In a first set of embodiments, an article of manufacture includes a cylinder insert of single crystal sapphire. The axis of the cylinder insert is aligned with an axis of symmetry of the single crystal. The cylinder insert is configured to be included in a rotor assembly that is configured to receive a sample for solid state nuclear magnetic resonance measurements and which rotor assembly is configured to be placed in a recess of a stator of a solid state nuclear magnetic resonance measurement system. The cylinder insert is a separate component of the rotor assembly from the rotor body. A length of the cylinder insert is less than a length of the rotor body to allow sufficient space inside the rotor body for the sample. The cylinder insert is configured to rotate at a known angle and a known fraction of an angular speed of the rotor body when the rotor assembly is inside the recess of the stator during operation of the nuclear magnetic resonance measurement system.

In some embodiments of the first set, the cylinder insert is configured to fit snugly inside the rotor. In some embodiments, the cylinder insert is external to the rotor body and the cylinder insert is shaped to engage a reciprocal shape in the rotor body such that rotation of the rotor body inside the recess of the stator causes the cylinder insert to rotate. In some embodiments, the cylinder insert forms an endcap or sleeve of the rotor body. In some embodiments, the cylinder insert forms a spacer adjacent an endcap of the rotor. In some embodiments, the rotor body is made in the greater part of zirconia.

In a second set of embodiments, a method for operating a solid state nuclear magnetic resonance measurement system includes inserting, into a recess of a stator of the system, a rotor assembly that includes a cylindrical insert or a rotor body holding a sample for solid state nuclear resonance measurement. The cylindrical insert is a separate component of the rotor assembly from the rotor body. The cylindrical insert or rotor body includes a single crystal sapphire; wherein: the axis of the cylindrical insert or rotor is aligned with an axis of symmetry of the single crystal. The method further includes causing the rotor and any cylindrical insert to rotate at a known rotational frequency and known angle relative to an axis of rotation of the rotor assembly. Still further, the method includes applying a directional magnetic field. Even further still, the method includes adjusting an orientation of the stator until a measured signal from aluminum atoms in the sapphire crystal achieves a maximum response value, whereby the orientation of the stator is within a thousandth of a degree of a magic angle that is 54.7356 degrees with respect to the applied magnetic field. In addition, the method includes, after adjusting the orientation of the stator, collecting solid state nuclear magnetic resonance measurements from the sample in the rotor without first replacing the rotor assembly.

In a third set of embodiments, a method for operating a solid state nuclear magnetic resonance measurement system includes inserting, into a recess of a stator of the system, a rotor body holding a sample for solid state nuclear resonance measurement. The rotor body, or a cylindrical insert that is a separate component of a rotor assembly from the rotor body but in the recess with the rotor, includes a single crystal sapphire. The axis of the rotor or the cylindrical insert is aligned with an axis of symmetry of the single crystal. The method also includes causing the rotor assembly to rotate at a first rotational frequency. The method further includes applying a directional magnetic field. Still further, the method includes determining a current angle based on separation of peaks in a measured signal from aluminum atoms in the sapphire crystal. Even further still, the method includes adjusting an orientation of the stator until the current angle is within a desired tolerance of a target measurement angle different from a magic angle that is 54.7356 with respect to the applied magnetic field. Yet further still, the method includes, after adjusting the orientation of the stator, collecting solid state nuclear magnetic resonance measurements from the sample in the rotor body without first replacing the rotor assembly.

Still other aspects, features, and advantages are readily apparent from the following detailed description, simply by illustrating a number of particular embodiments and implementations, including the best mode contemplated for carrying out the invention. Other embodiments are also capable of other and different features and advantages, and its several details can be modified in various obvious respects, all without departing from the spirit and scope of the invention. Accordingly, the drawings and description are to be regarded as illustrative in nature, and not as restrictive.

### BRIEF DESCRIPTION OF THE DRAWINGS

Embodiments are illustrated by way of example, and not by way of limitation, in the figures of the accompanying drawings in which like reference numerals refer to similar elements and in which:

FIG. 1A through FIG. 1E are block diagrams that illustrates an example SSNMR system, probe, stator and rotor assembly in the prior art;

FIG. 2 is a plot that illustrate example effects of rotating a sample at the magic angle in the prior art;

FIG. 3 is a block diagram that illustrates spatial relationships between a crystal axis (c-axis) of a sapphire component, such as an insert, and a reorientation angle θr, according to an embodiment;

FIG. 4A through FIG. 4D are plots that show example dependence of NMR responses of aluminum atoms in a sapphire crystal with crystal axis angle relative to the magnetic field, according to an embodiment.

FIG. 5 is a flow chart that illustrates an example method for using a sapphire crystal rotor or insert to set a desired non-magic angle during SSNMR measurements, according to an embodiment;

FIG. 6A and FIG. 6B are block diagrams that illustrate example sapphire inserts that can be used to set angles using rotors with relevant target sample materials, according to various embodiments; and

FIG. 7 is a flow chart that illustrates an example method for using a sapphire crystal insert to set the magic angle during SSNMR measurements, according to an embodiment.

### DETAILED DESCRIPTION

A method and apparatus are described for using a single crystal of sapphire to set stator angles during solid state nuclear magnetic resonance (SSNMR) measurements. In the following description, for the purposes of explanation, numerous specific details are set forth in order to provide a thorough understanding of the present invention. It will be apparent, however, to one skilled in the art that the present invention may be practiced without these specific details. In other instances, well-known structures and devices are shown in block diagram form in order to avoid unnecessarily obscuring the present invention.

Notwithstanding that the numerical ranges and parameters setting forth the broad scope are approximations, the numerical values set forth in specific non-limiting examples are reported as precisely as possible. Any numerical value, however, inherently contains certain errors necessarily resulting from the standard deviation found in their respective testing measurements at the time of this writing. Furthermore, unless otherwise clear from the context, a numerical value presented herein has an implied precision given by the least significant digit. Thus, a value 1.1 implies a value from 1.05 to 1.15. The term “about” is used to indicate a broader range centered on the given value, and unless otherwise clear from the context implies a broader range around the least significant digit, such as “about 1.1” implies a range from 1.0 to 1.2. If the least significant digit is unclear, then the term “about” implies a factor of two, e.g., “about X” implies a value in the range from 0.5X to 2X, for example, about 100 implies a value in a range from 50 to 200. Moreover, all ranges disclosed herein are to be understood to encompass any and all sub-ranges subsumed therein. For example, a range of “less than 10” for a positive only parameter can include any and all sub-ranges between (and including) the minimum value of zero and the maximum value of 10, that is, any and all sub-ranges having a minimum value of equal to or greater than zero and a maximum value of equal to or less than 10, e.g., 1 to 4.

Some embodiments of the invention are described below in the context of zirconia rotor body and sapphire insert. However, the invention is not limited to this context. In other embodiments other sapphire or non-sapphire or non-zirconia rotor bodies are used with or without a sapphire insert, as long as either the rotor body or an insert includes a single sapphire crystal.

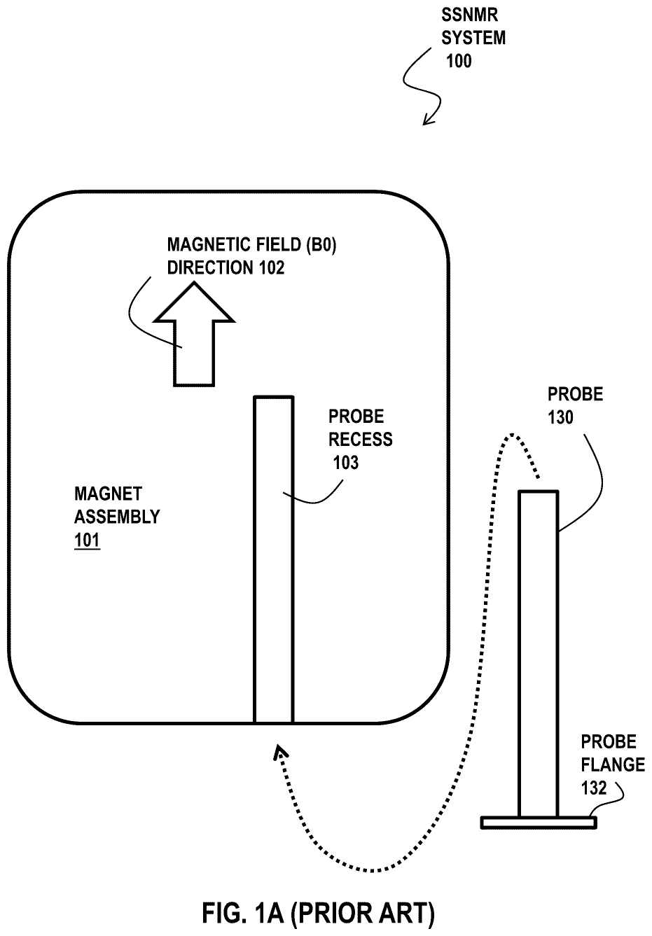

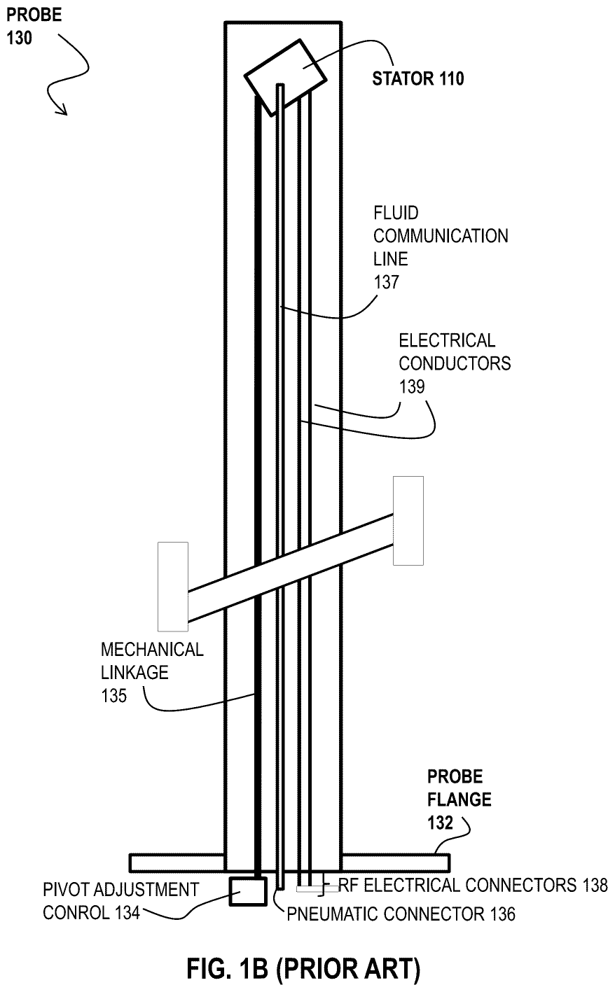

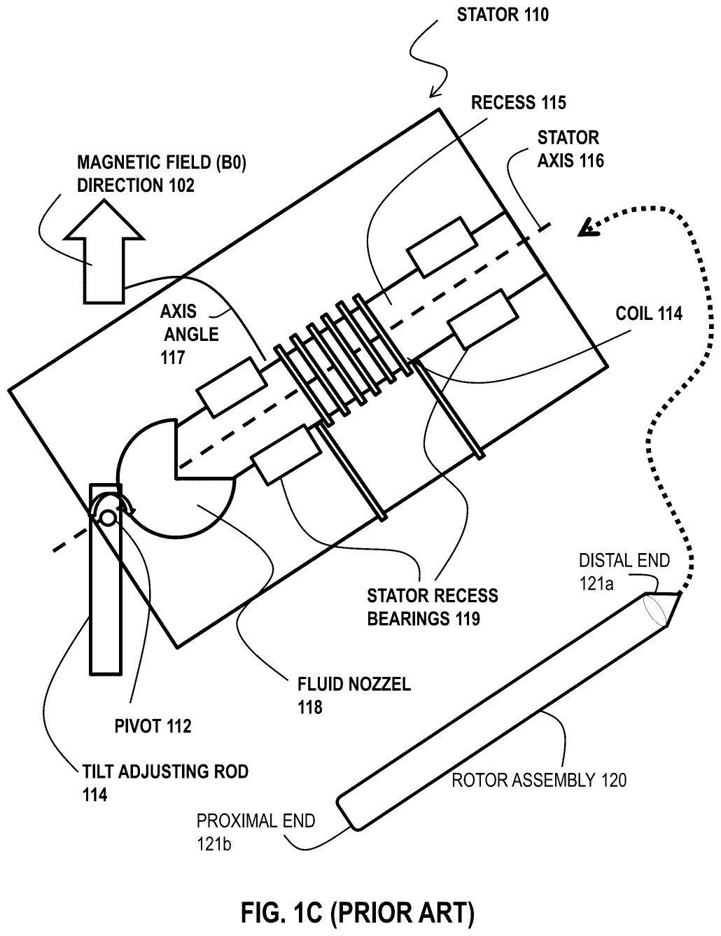

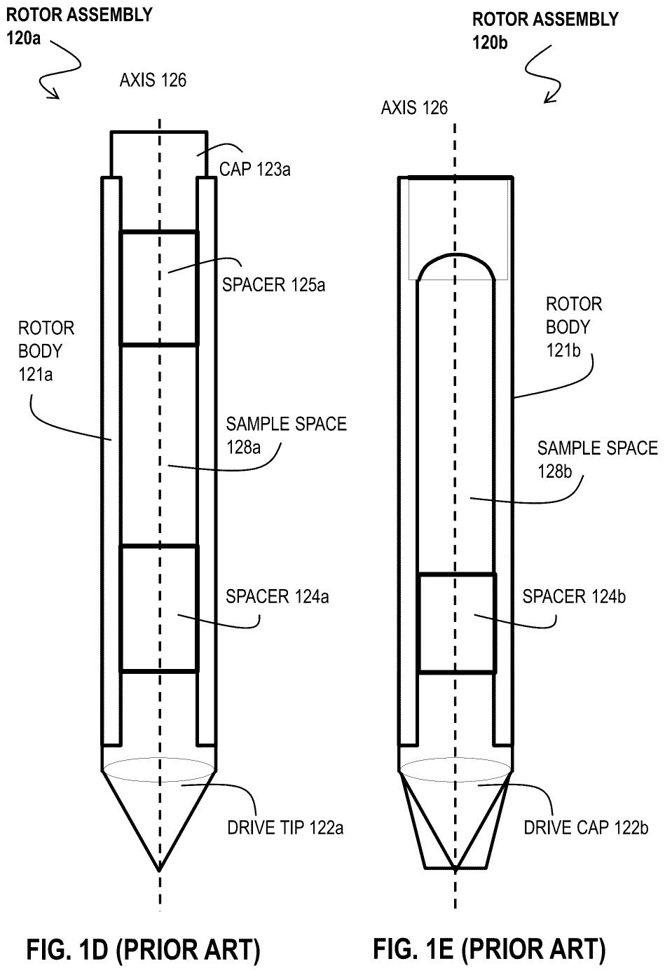

FIG. 1A through FIG. 1E are block diagrams that illustrates an example SSNMR system 100, probe 130, stator 110 and rotor assembly 120 in the prior art. FIG. 1A illustrates an SSNMR measurement system 100 that includes a magnet assembly 101 that produces a magnetic field B0 in a direction 102. The magnet assembly 101 includes a recess 103 configured to receive a probe 130 that is configured to hold a sample of interest to be measured. The probe 130 is configured to be attached to the assembly 101 by one or more fasteners through probe flange 132.

FIG. 1B illustrates a probe 130. The probe includes a stator 110 configured to orient a sample in the magnetic field B0 and, adjacent to the flange 132, an interface that includes a stator pivot adjustment control 134, a pneumatic connector 136, and two connectors 138 for RF electrical signals. The pivot adjustment control 134 is connected to the stator 110 through a mechanical linkage 135; the pneumatic connector 136 is connected to the stator 110 through a fluid communication line 137; and the RF electrical connectors 128 are connected to the stator 110 through corresponding electrical conductors 139.

FIG. 1C illustrates a stator 110. The stator 110 is configured to be oriented relative to the direction 102 of a strong applied magnetic field B0 by movement of pivot 112 by adjusting a tilt adjustment rod 114, either manually through a mechanical linkage 135, to a pivot adjustment control 134 such as thumbscrews, or automatically, such as by operation of one or more stepping motors to move the horizontal or vertical position of the pivot. The stator 110 includes a recess 115 for removably receiving a rotor assembly 120. The axis of that recess 115 is also called the stator axis 116 indicated by a dashed line segment. The angle between the direction 102 of the applied magnetic field B0 and the stator axis 116 is the stator axis angle 117, also called the reorientation angle about which a sample is rotated to remove anisotropies in the sample's NMR signal.

At a distal end of the stator recess 115 is a fluid nozzle 118 for directing a fluid into the recess 115 in order to suspend the rotor assembly 120 in the recess 115 and drive its rotation about the axis 116 of the recess 115. A distal end 121a of the rotor assembly 120 is configured to nest in the fluid nozzle 118. The opposite end of the rotor assembly 120 is called the proximal end 121b. The fluid nozzle 118 is supplied with fluid via the fluid communication line 137 and the pneumatic connector 136 by a fluid supply (not shown). Along the sides of the recess are one or more stator recess bearings 119 configured to keep the rotor assembly 120 aligned in the recess 115 with little friction. In some embodiments, the bearing 119 include fluid flow from the nozzle 118 or fluid communication line 137. Surrounding the recess 115 is an electrical conductor coil 114 configured to emit a radio frequency electromagnetic pulse that perturbs the nuclei in the recess 115, such as in a rotor assembly 120 inserted into the recess 115 (and any sample inside the inserted rotor assembly 120), and to receive the radio frequency electromagnetic signal emitted by the perturbed nuclei in response to that pulse.

FIG. 1D illustrates an example pencil rotor assembly 120a. The rotor assembly includes an at-least-partially hollow cylindrical rotor body 121a and a drive tip 122a, typically outfitted with fins configured to cause the rotor assembly to rotate in any fluid flow ejected by the fluid nozzle 118. The rotor body is configured to receive and hold a material sample in sample space 128a, and thus, in some embodiments, the rotor assembly may include, in addition to the rotor body 121a, one or more endcaps, such as cap 123a, or spacers, such as spacer 124a or spacer 125a, or some combination to seal the hollow portion of the rotor body 121a or fill any volume not filled by the material sample, or some combination. In some embodiments, the fins 122 are an integral part of a distal endcap. The speed of rotation of the rotor assembly, also called the rotational frequency or sample reorientation rate, is controlled by the attack angle of the fins and the speed of the fluid flow ejected by the fluid nozzle 118, which in turn is dependent on the pressure applied to the fluid supply in fluid communication with the nozzle. The rotor assembly 120a is configured to rotate about its central axis 126 during reorientation.

FIG. 1E illustrates another configuration for a rotor assembly. This embodiment includes a cylindrical rotor body 121b closed at the proximal end and a removeable drive endcap 122b at an open, distal end of the rotor body. This embodiment also includes a sample space 128b and a spacer 124b. The rotor assembly 120b is also configured to rotate about its central axis 126 during reorientation.

During SSNMR measurements, solid samples are packed within the cylindrical sample space (e.g., 128a or 128b) of a rotor body (e.g., 121a, 121b) which is rotated within the stator through the application of bearing gas at bearings 119 to suspend the rotor and drive gas through nozzle 118 to apply torque via fins in distal cap (e.g., drive tip 122a or drive cap 122b). The faster the sample is rotated, called the sample reorientation rate, the stronger the interactions that may be averaged out, and for this reason there has been significant development of this technology resulting in the achievement of sample reorientation rates exceeding 100 kilohertz (kHz, 1 kHz=103 Hertz, where a Hertz is one cycle per second). Typical MAS reorientation rates for biomolecular NMR studies detecting nuclei such as ³¹P, ¹³C, and ¹⁵N are around 10 kHz to 30 kHz, but H-detected NMR requires much faster MAS reorientation rates to sufficiently average homonuclear dipolar couplings.

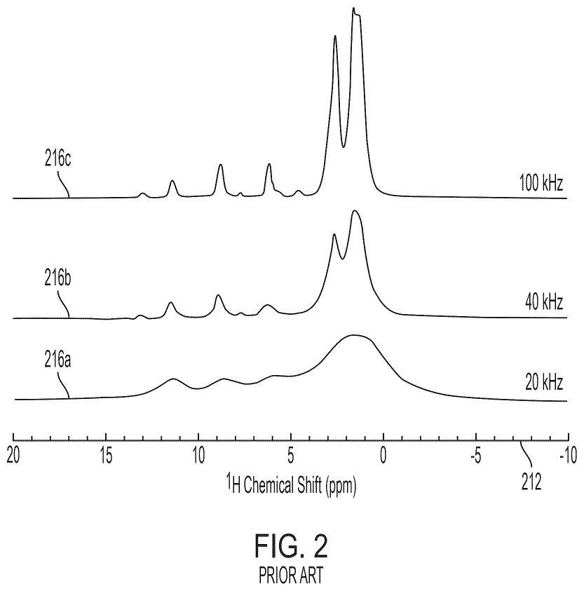

FIG. 2 is a plot that illustrates example effects of rotating a sample at the magic angle in the prior art. In FIG. 2, the horizontal axis 212 is the ¹H chemical shift (change in resonance of a hydrogen proton due to chemical context) expressed in parts per million (ppm). The vertical axis is energy at each shift, offset to separate different traces. A different peak is expected for each hydrogen atom bound to different atoms in different places in a molecule. In this example, the molecule is identified as N-acetylvaline (NAV) that has 11 hydrogen atoms bound to carbon or nitrogen atoms in the vicinity of oxygen atoms. Trace 216a shows the signal at a reorientation rate of 20 kHz. There is a suggestion of several peaks, but they are blurred together. Trace 216b shows greater prominence and separation of the peaks at a reorientation rate of 40 kHz. Trace 216c shows even greater prominence and separation of five or more clearly distinct and prominent peaks at a reorientation rate of 100 kHz.

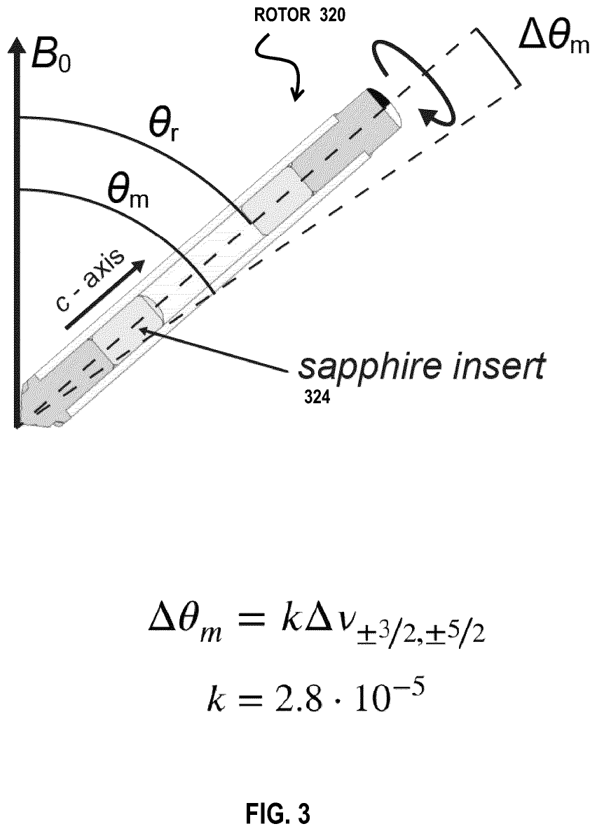

According to various embodiments, the ²⁷Al signal of a single crystal sapphire is used to determine and set an angle for the rotor axis 116 between +and −90 degrees of the magic angle. FIG. 3 is a block diagram that illustrates spatial relationships between a crystal axis (c-axis) of a sapphire component, such as an insert, and a reorientation angle θr, according to an embodiment. The Al ions occupy sites of threefold symmetry about an axis parallel to the labeled c-axis, yielding an axially symmetric Al electric field gradient (EFG) tensor.

The c-axis of a single crystal sapphire is aligned with the rotor's axis of symmetry 126, as shown in FIG. 1D or FIG. 1E. Cylindrical sapphire rotors have historically been used as an alternative to zirconia rotors in MAS experiments. Single-crystal sapphire rotors are commercially available and are used in DNP-NMR experiments for their superior microwave transmission properties, excellent thermal conduction, and, in the case of photochemically-induced DNP, optical transmission properties but have weaker mechanical properties compared to zirconia, making them prone to shattering during experiments.

In various embodiments, single-crystal sapphire rotors or other single crystal sapphire components, such as insert 324 of rotor 320, are used to directly measure in situ the offset Δθm of the reorientation rotation axis θr from the magic angle θm. All angles are defined relative to the z direction of magnetic field B₀. Using a cylindrical rotor primarily comprised of a single α-Al₂O₃ crystal domain with the c-axis aligned with the rotor's axis of symmetry 126, it is demonstrated that the Al satellite transition frequencies under MAS show a linear dependence on θr for values close to the magic angle. A measurement of the frequency difference between the (± 3/2, ± 5/2) outer satellite transitions can be used to obtain offset from the magic angle with high precision, as suggested by the equation in FIG. 3 which is just Equation 11, as described in more detail below.

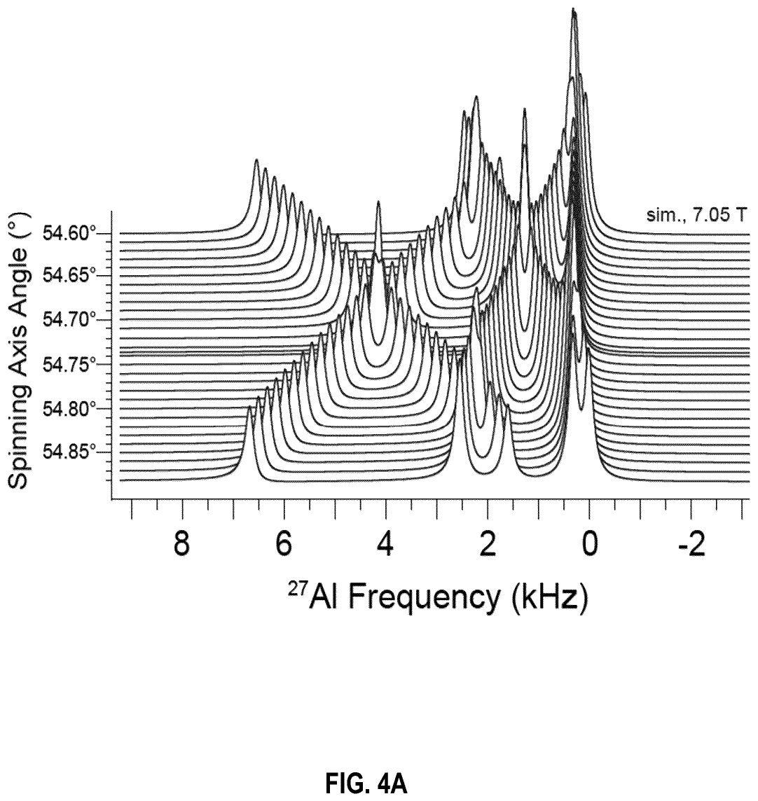

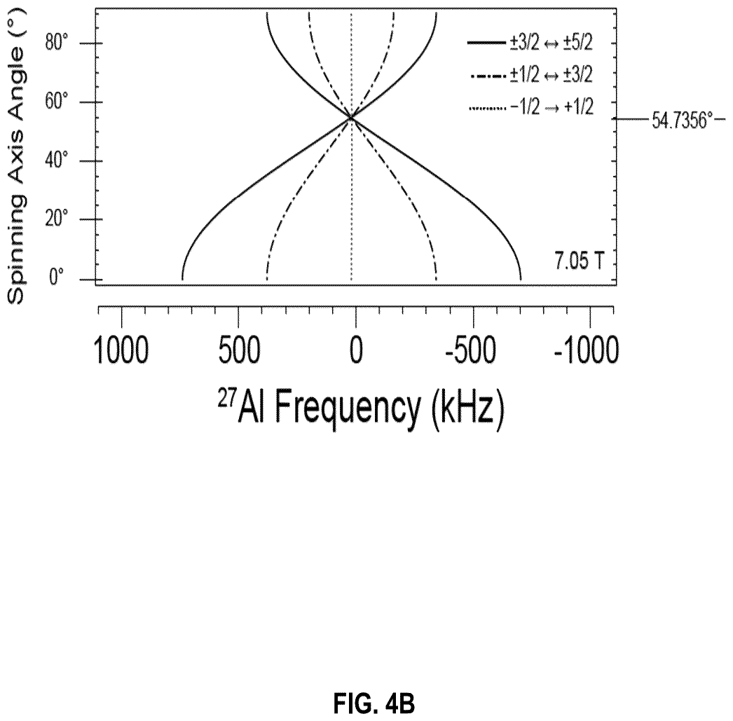

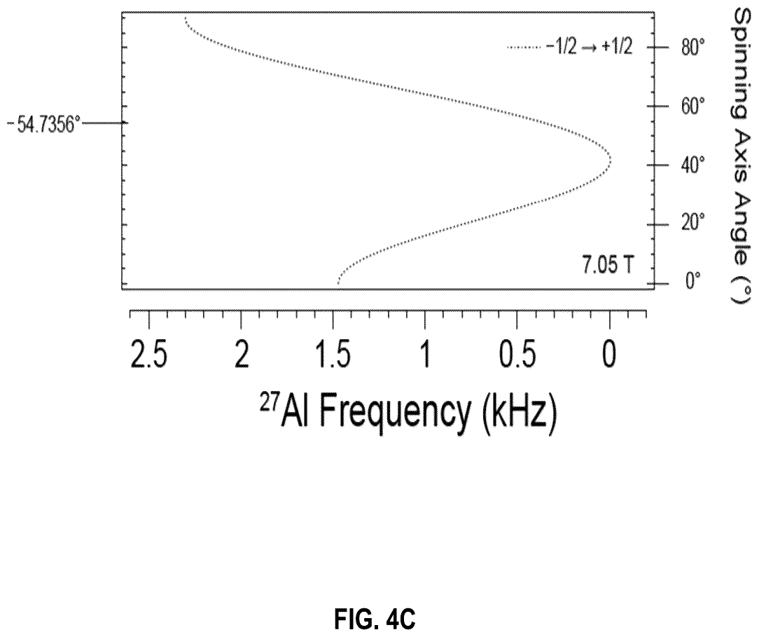

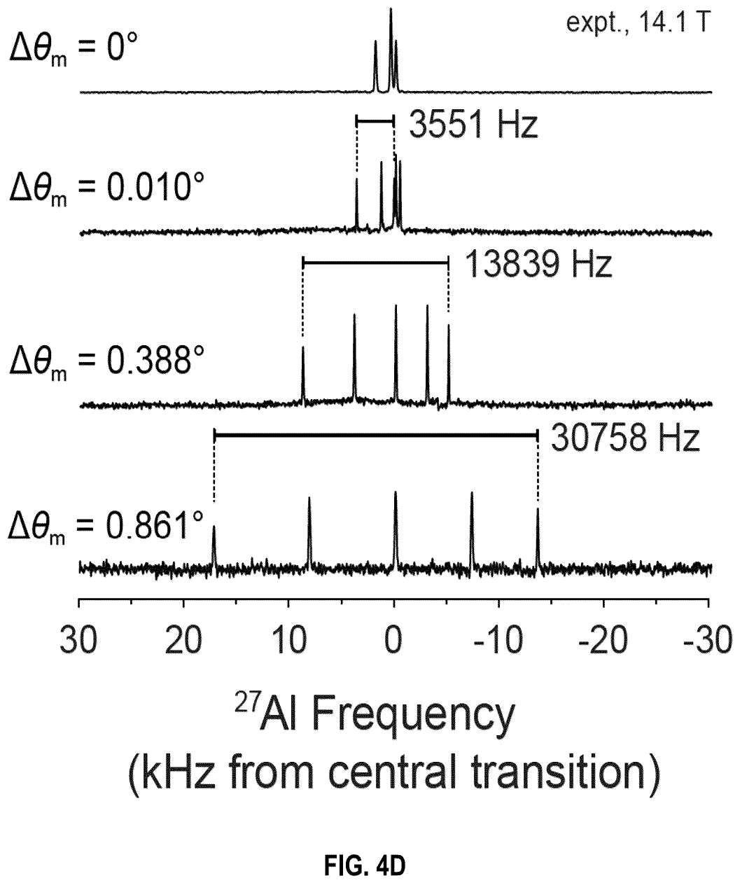

FIG. 4A through FIG. 4D are plots that show example dependence of NMR responses of aluminum atoms in a sapphire crystal with crystal axis angle relative to the magnetic field, according to an embodiment.

FIG. 4A shows simulated NMR spectra as a function of θr for the ²⁷Al resonance of a sapphire single crystal with the c-axis aligned with the rotor's rotational axis 126, with a rotation rate of 8.000 kHz in a magnetic field of strength 7.05 Tesla (T). For each angle, the horizontal axis indicates frequency of the NMR signal for the nucleus of ²⁷Al. On the magic angle, three peaks are present, corresponding to the central transition at the lowest (rightmost) frequency, the (±½, ± 3/2) inner satellite transitions at the middle frequency, and the (± 3/2, ± 5/2) outer satellite transitions at the highest (leftmost) frequency. At θr values different from the magic angle, even offset by only a few thousandths of a degree, both satellite transition frequencies manifest a measurable splitting. In some embodiments, this splitting measured during operation of the SSNMR system can indicate the angle at which the SSNMR measurement of the sample is being made.

The ²⁷Al transition frequencies of single crystal α-Al₂O₃ under rapid sample rotation can be determined with good accuracy by considering the quadrupole interaction to second order as the only perturbation in the total Hamiltonian. The resonance (peak) frequency of the transition between energy levels (quantum states) m−1 and m for a single crystal under a high-frequency rotation of arbitrary angle with respect to the magnetic field (known as variable angle spinning and abbreviated VAS) is indicated by the symbol

$${ω}_{m - 1 , m}^{V A S} .$$

Derivation of the general solution to this problem has been detailed elsewhere. Such equations can be used when the reorientation axis is different from the crystal axis, which is allowed in some embodiments.

The scenario of a single crystal sapphire rotating about its c-axis affords some convenient simplifications when obtaining the equations for

$${ω}_{m - 1 , m}^{V A S} .$$

The EFG tensor at the ²⁷Al site in α-Al₂O₃ is axial, meaning η_{Q}=0, and as the EFG tensor is aligned with the rotor's axis of symmetry, the principal axis system (PAS) orientation of the EFG tensor can be described with Euler angles α=0 and β=0. Therefore, the quadrupolar shifts up to second order for this system and may be written as given in the following Equation 4 through Equation 8 in which C_{Q} is the quadrupolar coupling constant in Hertz (Hz), ω₀ is the Larmor frequency of the nucleus in radians per second (rad s⁻¹), and P₂ and P₄ are the second-and fourth-order Legendre polynomials, respectively.

$${ω}_{+ \frac{3}{2} , + \frac{5}{2}}^{V A S} = - 6 \frac{π {C}_{Q}}{10} {P}_{2} ( cos ( {θ}_{r} ) ) - \frac{1}{{ω}_{0}} {( \frac{π {C}_{Q}}{10} )}^{2} ( \frac{42}{5} + \frac{60}{7} {P}_{2} ( cos ( {θ}_{r} ) ) - \frac{1188}{70} {P}_{4} ( cos ( {θ}_{r} ) ) ) \qquad ( 4 )$$

$${ω}_{+ \frac{1}{2} , + \frac{3}{2}}^{V A S} = - 3 \frac{π {C}_{Q}}{10} {P}_{2} ( cos ( {θ}_{r} ) ) - \frac{1}{{ω}_{0}} {( \frac{π {C}_{Q}}{10} )}^{2} ( \frac{3}{10} + 3 {P}_{2} ( cos ( {θ}_{r} ) ) - \frac{27}{10} {P}_{4} ( cos ( {θ}_{r} ) ) ) \qquad ( 5 )$$

$${ω}_{- \frac{1}{2} , + \frac{1}{2}}^{V A S} = - \frac{1}{{ω}_{0}} {( \frac{π {C}_{Q}}{10} )}^{2} ( - \frac{12}{5} - \frac{48}{7} {P}_{2} ( cos ( {θ}_{r} ) ) - \frac{324}{35} {P}_{4} ( cos ( {θ}_{r} ) ) ) \qquad ( 6 )$$

$${ω}_{- \frac{3}{2} , - \frac{1}{2}}^{V A S} = 3 \frac{π {C}_{Q}}{10} {P}_{2} ( cos ( {θ}_{r} ) ) - \frac{1}{{ω}_{0}} {( \frac{π {C}_{Q}}{10} )}^{2} ( \frac{3}{10} + 3 {P}_{2} ( cos ( {θ}_{r} ) ) - \frac{27}{10} {P}_{4} ( cos ( {θ}_{r} ) ) ) \qquad ( 7 )$$

$${ω}_{- \frac{5}{2} , - \frac{3}{2}}^{V A S} = 6 \frac{π {C}_{Q}}{10} {P}_{2} ( cos ( {θ}_{r} ) ) - \frac{1}{{ω}_{0}} {( \frac{π {C}_{Q}}{10} )}^{2} ( \frac{42}{5} + \frac{60}{7} {P}_{2} ( cos ( {θ}_{r} ) ) - \frac{1188}{70} {P}_{4} ( cos ( {θ}_{r} ) ) ) \qquad ( 8 )$$

The location of the peaks from FIG. 4A are well fit by the results of the Equation 4 through Equation 8 using C_{Q}=2.403 megahertz (MHz, 1 MHz=10⁶ Hz) and ω₀=2×78.194 MHz.

Some simulations included the CSA interaction in addition to the quadrupolar coupling to second order. In the case of ²⁷Al, the magnitude of the CSA is much less than the quadrupolar interaction and it does not contribute significantly to the peak shifts. Clearly the resonance peaks of the outer spin states depend linearly on the reorientation rotation angle θr in this range. At any of these angles there is a unique combination of peaks predicted by Equations 4, 5, 7 and 8 (the peak predicted by Equation 6 does not vary much with the reorientation angle over this range). Using Equations 4, 5, 7 and 8, or a linear fit to their predicted peaks or peak separations, one can match the peaks of a measured signal to the predicted peaks of these Equations to deduce the axis angle 117 for the reorientation rotation. An example linear fit is given by Equation 11 as described below. Note that at the magic angle there are only three peaks, not as many as five, because two satellite transitions merge.

The ability to determine angle from location of peaks in the NMR signal response extends to angles from about 0 to about 90 degrees. The peaks predicted by Equation 4 through Equation 8 are plotted over a range of θr from 0 to 90° in FIG. 4B. The horizontal axis indicates the NMR response signal frequency content in kHz between about 1000 kHz and −1000 kHz; and the vertical axis indicates axis angle for the reorientation rotation in the range from 0 degrees to 90 degrees. Equation 4 and Equation 8 are represented by the two solid traces, Equation 5 and Equation 7 by the two dot dash traces, and the central transition Equation 6 by the dashed trace. FIG. 4B shows the splitting between the transitions growing to over 1 MHz in width. The dependence of the satellite and central transition frequencies on θr enables absolute measurement of θr even at values far off the magic angle and is extremely useful in applications such as VAS and SAS. For a precise measurement of θr, the satellite transition frequencies could be observed with an NMR probe capable of broadband excitation and detection, or by adjusting the probe tuning and shifting the center frequency.

The central transition frequency exhibits a markedly reduced dependence on θr, spanning only a couple kHz from 0 to 90°. FIG. 4C shows the dependence of the peak of Equation 6 on reorientation angle θr 117. The horizontal axis indicates the NMR response signal frequency content in kHz between about 2.5 kHz and 0 kHz; and the vertical axis indicates axis angle for the reorientation rotation in the range from 0 degrees to 90 degrees. When measurement systems span only a narrow bandwidth, the central transition could be more easily leveraged for this measurement due to its θr-dependence over a narrow bandwidth.

Whether using a wide or narrow bandwidth SSNMR measurement system, these results mean that a single sapphire crystal with its axis of symmetry aligned with the axis angle 118 of the rotor can be used to determine the reorientation angle 117 while simultaneously measuring the sample, i.e., without having to first use a standard rotor assembly and then removing the standard rotor assembly and inserting a sample rotor assembly with all the hazards of such an operation.

In some embodiments, the reorientation angle 117 is determined using Equation 9,Equation 10 or Equation 11, or some combination, derived below from Equation 4 through Equation 8, as described next.

The difference in frequency between the (± 3/2, ± 5/2) outer satellite transitions is the most sensitive to changes in θr, making it the most suitable observable for determining small offsets from the magic angle in applications such as setting the magic angle for routine MAS, or in off −MAS experiments. Taking the difference of Equation 4 and Equation 8 yields Equation 9.

$$Δ {ω}_{\pm \frac{3}{2} , \pm \frac{5}{2}}^{VAS} = 3 \frac{π {C}_{Q}}{5} ( 3 {cos}^{2} ( {θ}_{r} ) - 1 ) \qquad ( 9 )$$

Note that for all values of θr,

$$Δ {ω}_{\pm \frac{3}{2} , \pm \frac{5}{2}}^{VAS}$$

does not depend on ω₀, and therefore the difference in frequency between the (± 3/2, ± 5/2) outer satellite peaks at a given θr will be constant regardless of the measurement field. This is also true for the (±½, ± 3/2) inner satellite transition peaks.

In some embodiments, only angles θr close to the magic angle θm are of interest. In such embodiments, the resonance peaks of the satellite transitions can be approximated as having a linear dependence on θr. and gives the peak frequency change in hertz (v) rather than radians per second (ω) as in the equation above.

$${Δ𝓋}_{\pm \frac{3}{2} , \pm \frac{5}{2}}^{VAS} = \frac{π {C}_{Q}}{150 \sqrt{2}} ( Δ θ m ) \qquad ( 10 )$$

Solving Equation 10 for Δθm yields Equation 11.

$$Δ θ m = \frac{150 \sqrt{2}}{π {C}_{Q}} {Δ𝓋}_{\pm \frac{3}{2} , \pm \frac{5}{2}}^{VAS} = k {Δ𝓋}_{\pm \frac{3}{2} , \pm \frac{5}{2}}^{VAS} \qquad ( 11 )$$

Where k=2.801×10⁻⁵ degree seconds for α-Al₂O₃. Equation 11 can be used to quickly obtain Δθm from a simple measurement of the difference in resonance peak frequencies between the (± 3/2, ± 5/2) outer satellite peaks.

The efficacy of this method was demonstrated by experiments. FIG. 4D shows experimental ²⁷Al NMR spectra at 40 kHz reorientation rate and 14.1 T field for θr at various offsets (0°, 0.01°, 0.388°, and 0.861°) from the magic angle. The observed values of Δv (0 Hz, 3551 Hz, 13839 Hz, 30758 Hz) agreed with Equation 11 for these offsets from the magic angle.

Higher order effects have been shown to be negligible even at small offsets. When the splitting between the outer satellite transitions is zero, e.g., when the (± 3/2, ± 5/2) merged, outer satellite peak intensity is maximized, yet the value of θr is 54.73514°, which is an offset of −0.00047° from the magic angle. Thus, with respect to a magic angle setting protocol, if the setting which maximizes the intensity of this peak is taken as the calibrated magic angle, this guarantees a mis-set of less than a half-thousandth of a degree, which for most NMR experiments will have a negligible effect.

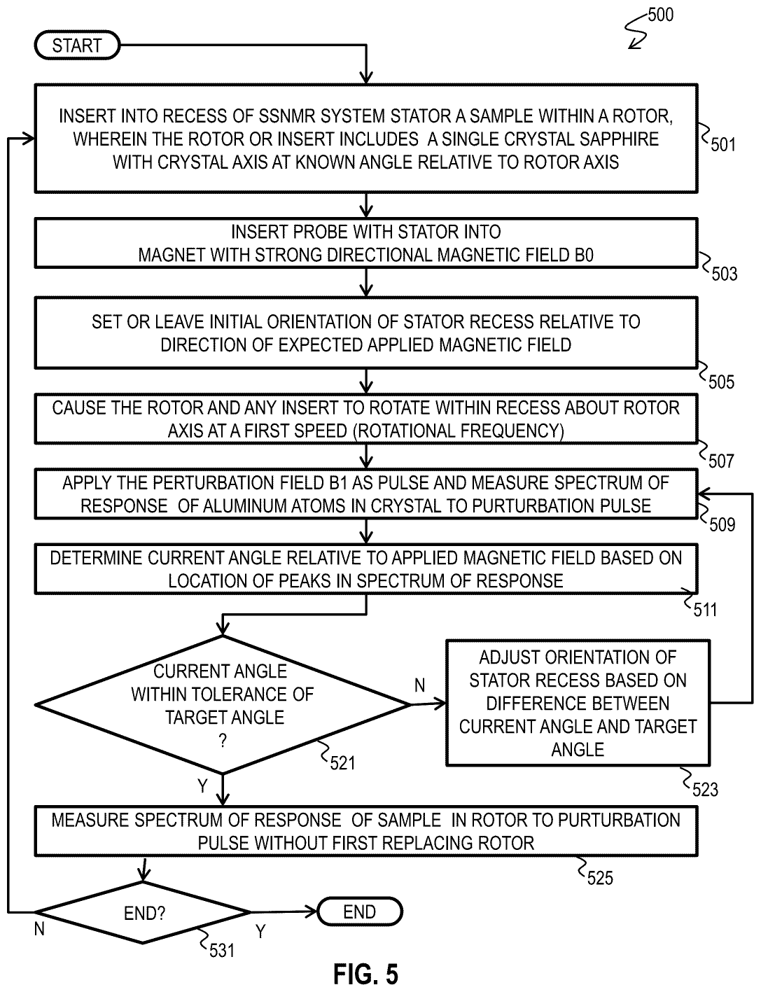

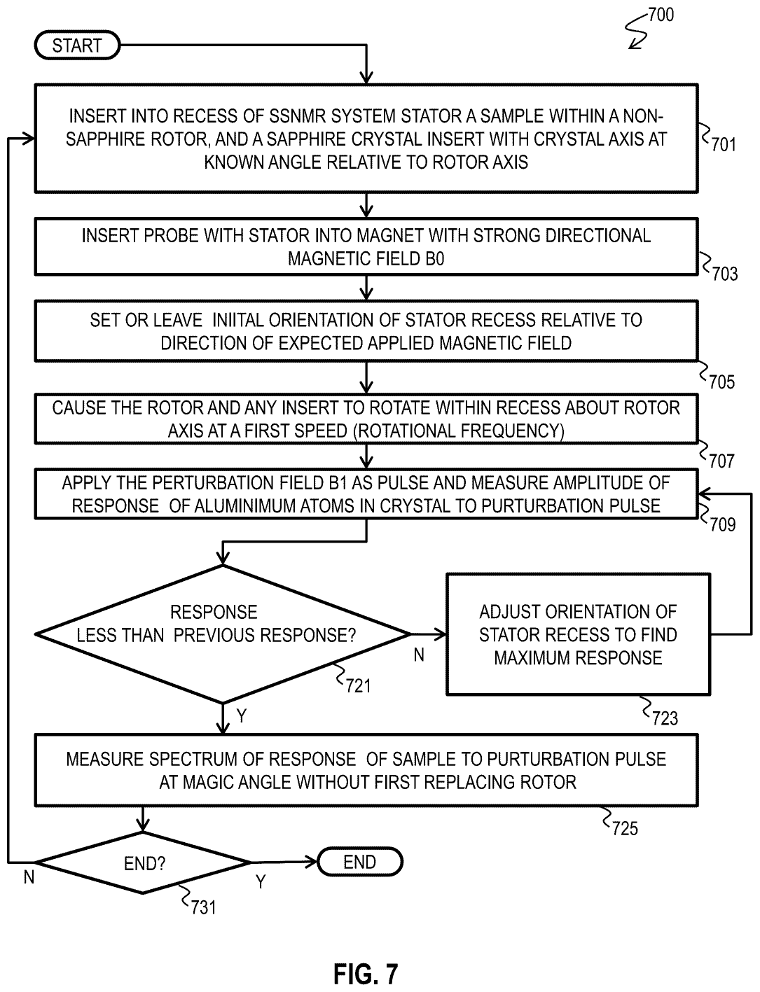

FIG. 5 is a flow chart that illustrates an example method 500 for using a sapphire crystal rotor or insert to set a desired angle during SSNMR measurements, according to an embodiment. Although steps are depicted in FIG. 5, and in subsequent flowchart FIG. 7, as integral steps in a particular order for purposes of illustration, in other embodiments, one or more steps, or portions thereof, are performed in a different order, or overlapping in time, in series or in parallel, or are omitted, or one or more additional steps are added, or the method is changed in some combination of ways.

In step 501, a rotor assembly 120 is inserted into recess of SSNMR system stator 110 of probe 130. The rotor assembly 120 includes a sample within a rotor body 121. Either the rotor body 121 or a separate insert (described below) includes a single crystal sapphire with crystal axis (c-axis) at a known angle relative to the rotor axis.

In step 503 the probe 130 is inserted into the recess 103 of magnet assembly 101, where a strong magnetic field B0 is applied in direction 102, e.g., using superconducting coils of the SSNMR system (not shown). As a result, the nuclei in the sample and sapphire crystal included in the rotor body 121 or any insert align with the magnetic field.

In step 505, an initial orientation of stator recess relative to direction of expected applied magnetic field (i.e., axis angle 117) is set. For example, tilt adjusting rod 104 is adjusted manually or automatically using pivot adjustment control 137 to set the axis angle 117 at a predetermined value that approximates a desired angle for SSNMR measurements, or left at a previously set value.

In step 507, the probe, including the rotor body 121 and any insert 430/432, is caused to rotate within recess of stator 110 about rotor axis at a first speed (rotational frequency or reorientation rate). For example, a fluid, such as a gas, is supplied at pneumatic connector 136 and expelled from nozzle 118 to engage fins of the rotor assembly 120 and thus apply toque to rotate the rotor assembly 120 and to suspend the rotor assembly at bearings 119 to reduce friction. By varying the pressure supplying the fluid to the nozzle the rotor assembly 120 (and thus the rotor body 121 and any insert) will vary its speed of rotation. As a result, the nuclei in the sample and sapphire crystal respond to the applied magnetic field B0, removing anisotropic and other undesirable effects during SSNMR measurements.

In step 509 a radio frequency (RF) magnetic pulse B1 is emitted by coil 114 to perturb the nuclei in the sample and the sapphire crystal aligned by the magnetic field B0 to a different energy spin state. After the pulse, the perturbed nuclei in the sample and sapphire crystal move to different spin states and emit RF electromagnetic signals picked up by coil 114. That signal is decomposed to its spectral content by Fourier analysis to produce a spectral response signal, such as those depicted in FIG. 2, FIG. 4A and FIG. 4D. Step 509 includes determining the response spectrum attributed to the ²⁷Al atoms in the sapphire crystal. Thus, step 509 includes measuring the spectrum of response of aluminum atoms in the single sapphire crystal to the perturbation pulse.

In step 511, current angle, θr, relative to direction 102 of applied magnetic field B0, is determined based on location of peaks in spectrum of ²⁷Al response, e.g., using one or more of Equation 4 through Equation 11.

In step 521, it is determined whether current angle θr is within tolerance, e.g., within one thousandth of a degree, of target angle. In some embodiments, e.g., in embodiments using a sapphire insert separate from a non-sapphire rotor, the target angle is the magic angle. In other embodiments, including embodiments using a sapphire rotor and no sapphire insert, or a non-sapphire rotor and a sapphire insert, the target angle is a non-magic angle.

If not, then control passes to step 523. In step 523, the orientation of stator 110 and thus its recess, is adjusted based on difference between current angle θr and target angle. For example, if the target angle is larger than the current angle, the tilt adjustment rod 104 is move manually or automatically to increase the tilt of the stator axis 116. Similarly, if the target angle is smaller than the current angle, the tilt adjustment rod 104 is move manually or automatically to decrease the tilt of the stator axis 116. Control then passes back to repeat some or all of steps 509 through 521.

If it is determined in step 521 that the current angle θr is within desired tolerance of target angle, then control passes to step 525. In step 525, the spectrum of the response of the sample in rotor to the perturbation pulse is measured without first replacing the rotor.

In step 531, it is determined whether end conditions are satisfied, e.g., whether another independent measurement is to be made. If not, control passes back to the beginning, step 501 and following. Otherwise, the process ends.

In some embodiments, instead of replacing the whole rotor body 121 with sapphire, one can replace just a small part of the rotor assembly 120, a spacer or portion of one of the caps (collectively referenced herein as a “rotor insert,” “cylindrical insert,” cylindrical sapphire insert,” “sapphire insert,” or simply “insert”) and still be able to measure the magic angle or other angle of rotor body rotation while continuing to use existing zirconia or other non-sapphire rotors while samples are inside the rotor. The insert is thus an accessory for the many thousands of existing solid-state NMR rotors, which could be used with minor modifications in protocol by anyone currently using KBr to set their magic angle with a standard sample, e.g., due to less brittleness, greater strength, and little need for high microwave, visible light or thermal transmissivity, or other advantage of non-sapphire rotors.

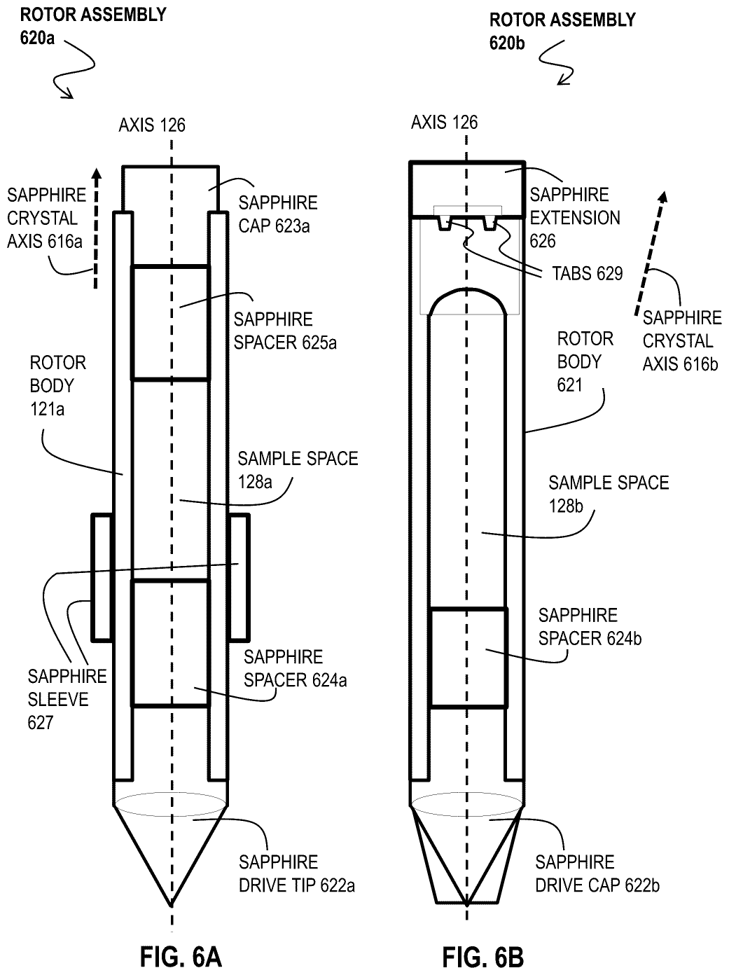

FIG. 6A and FIG. 6B are block diagrams that illustrate example sapphire inserts that can be used to set angles using non-sapphire rotor bodies with relevant target sample materials, according to various embodiments. FIG. 6A illustrates an example pencil rotor assembly 620a with one or more sapphire inserts, according to various embodiments. As in FIG. 1D, rotor assembly 620a, 620b (collectively referenced as rotor assembly 620) includes an at-least-partially hollow cylindrical rotor body 121a and a drive tip 622a, typically outfitted with fins configured to cause the rotor assembly to rotate in any fluid flow ejected by the fluid nozzle 118. The rotor body 121a is configured to receive and hold a material sample in sample space 128a. In various embodiments one or more of the other components are made of a single crystal of sapphire. Thus, in various embodiments, the rotor assembly may include, in addition to the rotor body 121a, one or more single crystal sapphire endcaps, such as sapphire cap 623a, or single crystal sapphire spacers, such as sapphire spacer 624a or sapphire spacer 625a, or some combination to seal the hollow portion of the rotor body 121a or fill any volume not filled by the material sample, or some combination. In some embodiments, fins are an integral part of a distal endcap, such as sapphire drive tip 622a.

FIG. 6B illustrates a different example rotor assembly 620 with one or more sapphire inserts, according to various embodiments. This embodiment includes a cylindrical rotor body (e.g., body 621, or body 121b depicted in FIG. 1E) that is closed at the proximal end and a single crystal sapphire removeable drive endcap 622b at an open, distal end of the rotor body 121b. This embodiment also includes a sample space 128b and a single crystal sapphire spacer 624b.

In some embodiments, additional single crystal sapphire inserts are added, such as sapphire sleeve 627 depicted in FIG. 6A or a sapphire extension 626 shown in FIG. 6B. In some embodiments using a sapphire extension 626, the extension is engaged to rotate with the rest of the rotor assembly, e.g., by including tabs 629 or other protrusions that fit into corresponding shapes in the rotor body 621. In general, a single crystal sapphire insert can make up: a spacer with disk shape, cylinder shape, among other shapes; a sleeve external to the rotor body; a sleeve internal to the rotor body; cap; drive tip; insert that fits into a recess within a cap; an insert that fits into a recess within the stator; or an insert that fits into a recess within the rotor body; or some combination.

In all such embodiments, the single crystal axis (c-axis) of any sapphire component of the rotor assembly 620a or 620b is oriented at a known angle compared to the rotor body axis of rotation 126, whether parallel to same as shown by c-axis 616a or not as shown by c-axis 616b.

In some embodiments, the sapphire inserts are shaped to fit existing rotor bodies used in existing rotor assemblies. Rotor bodies come in various shapes and sizes, ranging from 14 mm outer diameter to 0.7 mm outer diameter. Spherical rotors exist, and other geometries too. In some embodiments, the insert has the same diameter as the outer diameter as the rotor body, such as 1.6 millimeters, and a length that is short compared to the length of the rotor body, so that a conventional stator recess can accommodate both rotor body 121a or 121b and insert and sample. For example, the length of the insert is selected in a range from about 0.5 mm to about 1.5 mm. In an example embodiment, the insert length is 1.2 mm. A rotor assembly is then formed that includes both a traditional or other non-sapphire rotor body 121a or 121b and a sapphire insert. In some embodiments, the rotor assembly is configured so that both the rotor and the insert rotate coaxially and at the same rotation rate when the rotor assembly is rotated by the fluid passing past the fins of the drive tip 622a, 122a, or drive cap 622b or 122b.

In some embodiments, the cylinder insert is configured to fit snugly inside the rotor. For example, the insert has an outer diameter that is equal to an interior diameter of the rotor. Some rotors have an interior diameter of about 0.3 mm less than the outer diameter, so in some embodiments the cylindrical sapphire insert has an outer diameter of 1.1 mm. In some of these embodiments, the cylindrical sapphire insert has a length of 1.2 mm so as to leave sufficient space inside the rotor for a sample to be subjected to SSNMR measurement.

In some embodiments, the insert is a precision-machined cylinder that fits snugly and is wedged in the rotor body coaxially such that no “keyways” or anything are needed to align and/or couple the insert with the rotor body. In another embodiment, the insert fits inside a hole on the bottom of a vespel cap.

In some embodiments, the inserts are used during the method 500 of FIG. 5 to set the magic or non-magic angle for SSNMR measurements. In some embodiments, only the magic angle is of interest. In such embodiments, the insert is used to set the magic angle for a SSNMR measurement according to the method 700 of FIG. 7.

FIG. 7 is a flow chart that illustrates an example method for using a sapphire crystal insert to set the magic angle during SSNMR measurements, according to an embodiment. In step 701, a rotor assembly is inserted into a recess of SSNMR system stator 110. The rotor assembly includes a sample within a sapphire rotor body 121 or a non-sapphire rotor with a separate insert (e.g., one or more of 630, 632, 634, 636, 638). The insert, if any, includes a single crystal sapphire with crystal axis at a known angle relative to the rotor axis.

In step 703, as in step 503, the probe 130 is inserted into the recess 103 of magnet assembly 101 where a strong magnetic field B0 is applied in direction 102, e.g., using superconducting coils of the SSNMR system (not shown). As a result, the nuclei in the sample and sapphire crystal included in the rotor body 121 or any insert align with the magnetic field.

In step 705, as in step 505, an initial orientation of stator recess relative to direction of expected applied magnetic field (i.e., axis angle 117) is set. For example, tilt adjusting rod 104 is adjusted manually or automatically using pivot adjustment control 137 to set the axis angle 117 at a predetermined value that approximates a desired angle for SSNMR measurements, or left at a previously set value.

In step 707, as in step 507, the rotor assembly, including the rotor body 121 and any insert, is caused to rotate within recess of stator 110 about rotor axis 126 at a first speed (reorientation rate). For example, a fluid, such as a gas, is expelled from nozzle 118 to engage fins of the rotor assembly and thus apply toque to rotate the rotor assembly and to suspend the rotor assembly at bearings 119 to reduce friction. By varying the pressure supplying the fluid to the nozzle the rotor assembly (and thus the rotor and any insert) will vary its speed of rotation. As a result, the nuclei in the sample and sapphire crystal along the axis of rotation align due to the applied magnetic field B0, removing anisotropic and other undesirable effects during SSNMR measurements.

In step 709, as in step 509, a radio frequency (RF) electromagnetic pulse is emitted by coil 114 to perturb the nuclei in the sample and the sapphire crystal aligned by the magnetic field B0 to a different energy spin state. After the pulse, the perturbed nuclei in the sample and sapphire crystal move to different spin states and emit RF electromagnetic signals picked up by coil 114. In contrast to step 509, in step 709, the amplitude of that response signal is determined. In some embodiments, this includes decomposing that signal into to its spectral content by Fourier analysis to produce a spectral response signal, such as those depicted in FIG. 2A, FIG. 4A and FIG. 4D. Step 709 includes determining the amplitude of one or more peaks in the response spectrum attributed to the ²⁷Al atoms in the sapphire crystal. Thus, step 709 includes measuring the spectrum of response of aluminum atoms in the crystal to perturbation pulse.

In step 721, it is determined whether the response at the current angle is greater than, or equal to, or less than, the response measured at a previous angle. If not less than at a previous angle, then the maximum response has not yet been confirmed and control passes to step 723 to continue to adjust the angle in the same direction as the last adjustment, and control passes back to repeat steps 705 through 721.

If it is determined in step 721 that the response at the current angle is less than at the previous angle then control passes to step 725. In step 725 it is determined that the previous angle was the magic angle, and the angle is reset to that value. Then, the spectrum of the response of the sample inside rotor to the perturbation pulse is measured at the magic angle without first replacing the rotor body or rotor assembly or probe.

In step 731, it is determined whether end conditions are satisfied, e.g., whether there is no other independent measurement to be made. If not, control passes back to the beginning, step 701 and following. Otherwise, the process ends.

### CONCLUSION

Currently, the most common way to set the magic angle is to use a separate rotor containing a sample that is sensitive to magic angle offset, and then setting the angle by observing NMR signal from that sample. After the angle is set, a rotor assembly 120 holding the standard is removed, and then a different rotor assembly 120 holding the sample of interest is inserted into the recess of the stator for measurement. In this process, it is typically assumed that the angle will be maintained during this transfer process, and that other environmental factors will not affect the angle. It has been determined that this is often not the case, and that typically the angle changes quite a lot during this process or under different rotating conditions. The sapphire components or the methods presented here, or some combination, solves the problem by enabling fine adjustment of the angle while rotating the sample of interest.

A sapphire component, such as an insert, can have multiple utilities in the context of the rotor assembly. For example, pencil-style rotors make use of fluorocarbon polymer spacers to center a sample. A sapphire spacer serves the same purpose as the fluorocarbon spacer, but now can give one in situ angle sensing capabilities where the fluorocarbon spacer could not. Caps for rotors are necessary to keep the sample in the rotor and are typically made of Vespel or other polymer, but a sapphire cap would allow one to contain the sample and get the angle sensing benefits of sapphire. In this way, one is not wasting any of the volume of the rotor that is allocated for the sample—one is just adding new functionality to existing parts of the rotor assembly. Previous implementations of putting angle-sensitive sample (like KBr) in the rotor along with your sample of interest reduce the total available sample volume.

What is claimed is:

1. An article of manufacture comprising a cylinder insert of single crystal sapphire; wherein:
the axis of the cylinder insert is aligned with an axis of symmetry of the single crystal;
a diameter of the cylinder insert is equal to either an internal or external diameter of a rotor that is configured to receive a sample for solid state nuclear magnetic resonance measurements and is configured to be placed in a recess of a stator of a solid state nuclear magnetic resonance measurement system;
the cylinder insert is a separate component from the rotor;
a length of the cylinder insert is less than a length of the rotor to allow sufficient space inside the rotor for the sample; and
the cylinder insert is configured to rotate coaxially and at a same angular velocity with the rotor when the cylinder insert is inside the recess of the stator during operation of the nuclear magnetic resonance measurement system.

2. The article as recited in claim 1; wherein the cylinder insert is configured to fit snugly inside the rotor.

3. The article as recited in claim 1; wherein the cylinder insert is external to the rotor and the cylinder insert is shaped to engage a reciprocal shape in the rotor such that rotation of the rotor inside the recess of the stator causes the cylinder to rotate.

4. The article as recited in claim 1; wherein the cylinder insert forms an endcap of the rotor.

5. The article as recited in claim 1; wherein the cylinder insert forms a spacer adjacent an endcap of the rotor.

6. The article as recited in claim 1; wherein the rotor is made in the greater part of zirconia.

7. A rotor assembly for SSNMR measurements comprising the article of manufacture as recited in claim 1 and the rotor body, wherein the rotor body does not include a single crystal sapphire.

8. A method for operating a solid state nuclear magnetic resonance measurement system, the method comprising:
inserting, into a recess of a stator of the system, a cylindrical insert and a rotor holding a sample for solid state nuclear resonance measurement, wherein the cylindrical insert is a separate component from the rotor, and wherein the cylindrical insert includes a single crystal sapphire; wherein: the axis of the cylindrical insert is aligned with an axis of symmetry of the single crystal;
causing the rotor to spin about an axis of the rotor at a first rotational frequency and the cylindrical insert to rotate at a known factor of the first rotational frequency and at a known relative angle to the axis of the rotor;
applying a directional magnetic field;
adjusting an orientation of the stator until a measured signal from aluminum atoms in the sapphire crystal achieves a maximum amplitude value, whereby the orientation of the stator is within a thousandth of a degree of a magic angle that is 54.7356 degrees with respect to the applied magnetic field;
after adjusting the orientation of the stator, collecting solid state nuclear magnetic resonance measurements from the sample in the rotor.

9. The method as recited in claim 8 wherein the known factor is 1.

10. The method as recited in claim 8 wherein the known relative angle is 0.

11. A method for operating a solid state nuclear magnetic resonance measurement system, the method comprising:
inserting, into a recess of a stator of the system, a cylindrical insert and a rotor holding a sample for solid state nuclear resonance measurement, wherein the cylindrical insert is a separate component from the rotor, and wherein the cylindrical insert includes a single crystal sapphire; wherein: the axis of the cylindrical insert is aligned with an axis of symmetry of the single crystal;
causing the rotor to spin about an axis of the rotor at a first rotational frequency and the cylindrical insert to rotate at a known factor of the first rotational frequency and at a known relative angle to the axis of the rotor;
applying a directional magnetic field;
determining a current angle based on separation of peaks in a measured signal from aluminum atoms in the sapphire crystal;
adjusting an orientation of the stator until the current angle is within a desired tolerance of a target measurement angle different from a magic angle that is 54.7356 degrees with respect to the applied magnetic field; and
after adjusting the orientation of the stator, collecting solid state nuclear magnetic resonance measurements from the sample in the rotor.

12. The method as recited in claim 11 wherein the known factor is 1.

13. The method as recited in claim 11 wherein the known relative angle is 0.
